(19) United States
(12) Patent Application Publication
(10) Pub. No.: US 2022/0157633 A1
(43) Pub. Date: May 19, 2022

(54) WAFER BONDING APPARATUS

(71) Applicant: Samsung Electronics Co., Ltd., Suwon-si (KR)

(72) Inventors: Masato KAJINAMI, Yokohama city (JP); Takamasa SUGIURA, Yokohama city (JP); Fumitaka MOROISHI, Yokohama city (JP)

(73) Assignee: Samsung Electronics Co., Ltd., Suwon-si (KR)

(21) Appl. No.: 17/385,095

(22) Filed: Jul. 26, 2021

(30) Foreign Application Priority Data
Nov. 17, 2020 (JP) 2020-190872
Dec. 16, 2020 (KR) 10-2020-0176111

(51) Int. Cl. H01L 21/68; H01L 21/683

(52) U.S. Cl. CPC H01L 21/681; H01L 21/6838

(57) ABSTRACT

A wafer bonding apparatus may include a first chuck, a second chuck, and a pressure device. The first chuck may include a hole formed through a central portion of the first chuck. The second chuck may have a hole formed through a central portion of the second chuck. The pressure device may be configured to pressurize a wafer toward the second chuck through the holes. An air bearing may be interposed between the pressure device and the first chuck to suppress a dislocation of the pressure device.

### CROSS-RELATED APPLICATION

This application claims priority under 35 USC § 119 to Japanese Patent Application No. 2020-190872, filed on Nov. 17, 2020, in the Japanese Patent Office and Korean Patent Application No. 10-2020-0176111, filed on Dec. 16, 2020, in the Korean Intellectual Property Office (KIPO), the contents of each of which are herein incorporated by reference in their entirety.

### BACKGROUND

### 1. Field

Example embodiments relate to a wafer bonding apparatus.

### 2. Description of the Related Art

In order to bond wafers to each other, bonding surfaces of the wafers may be activated using plasma. The activated bonding surfaces may vertically face each other. The bonding faces may then be bonded to each other. During the wafers being bonded to each other, air may exist between the wafers to generate a void between the bonded wafers. Central portions of the wafers may be pressurized to deform the wafers, thereby discharging the air between the bonded wafers.

Further, as a pitch a semiconductor device is narrowed, it may be required to bond the wafers in sub-micron accuracy. When any one of the wafers is pressurized in pressurizing the central portions of the wafers, expansion and contraction may be generated at the wafers. When the expanded and/or contracted wafers are bonded to each other, a dislocation of the wafers may be generated from the central portion to a circumferential surface in the wafers. The dislocation at the circumferential surface of the wafers may be no less than about 1 micron.

Therefore, in order to reduce the expansion and the contraction of the wafers, it may be useful to decrease a gap between the wafers.

Further, the dislocation of the wafers caused by the expansion and the contraction may be suppressed by a uniform expansion and contraction. However, when two pushers do not face each other and the pressurized portions of the wafers are also misaligned with each other, the dislocation of the wafers after bonding may also be generated.

Furthermore, because the gap between the wafers may be very narrow, when a tilt is formed between the wafers, edge portions of the wafers may make contact with each other to generate the void between the wafers. Thus, correction apparatuses may be used, as disclosed in Japanese Patent No. 6448848 and WO Publication No. 2010-058481. The correction apparatuses may include a load cell configured to detect a tilt of a wafer support by a load of wafers, thereby correcting the slope of the wafer support. However, when a parallelism of the wafer support is corrected using the load, a slight gap may be generated between the bonded wafers so that the bonded wafers may have posture different from a posture of the wafers on the wafer support having the corrected parallelism.

When the wafers are bonded to each other using the pushers, the wafers may be sequentially bonded from the central portion to the circumferential portion. Bonded interfaces between the wafers may spread from the central portion to the circumferential portion at different speeds. Thus, a pressurized time of the wafer using the pusher may be so long to decrease productivity.

Further, when the wafers are bonded to each other under vacuum, it may not be required to pressurize the central portions of the wafers because the air may not exist between the wafers. However, the productivity may also be reduced and a cost of the wafer bonding apparatus may be so expensive.

### SUMMARY

Example embodiments provide a wafer bonding apparatus capable of more accurately controlling a warpage and a parallelism of wafers, suppressing a dislocation of the wafers, accurately bonding the wafers to each other without a void, and improving productivity by monitoring a bonding process of the wafers.

According to example embodiments, a wafer bonding apparatus may include a first chuck, a second chuck, and a pressure device. The first chuck may include a hole formed through a central portion of the first chuck. The second chuck may have a hole formed through a central portion of the second chuck. The pressure device may be configured to pressurize a wafer toward the second chuck through the holes. An air bearing may be interposed between the pressure device and the first chuck to suppress a dislocation of the pressure device.

According to example embodiments, the dislocation of the pusher caused by distortion of the wafer may be suppressed to accurately bond the wafers to each other without a void between the wafers.

In example embodiments, the wafer bonding apparatus may further include a force sensor configured to detect a contact of the wafer.

According to example embodiments, the air bearing may function to reduce a resistance caused by a sliding friction to accurately detect a chucking surface on which the wafer may be chucked. Further, a gap between the wafers may be accurately controlled to suppress a difference between the distortions of the wafers, thereby accurately bonding the wafers to each other.

In example embodiments, the wafer bonding apparatus may further include a tilt sensor and a tilt stage. The tilt sensor may detect a tilt between a first wafer chucked by the first chuck and a second wafer chucked by the second chuck. The tilt stage may control a tilt of the second chuck based on the tilt detected by the tilt sensor to provide the first and second wafers with a parallelism.

According to example embodiments, the void may not be generated between the first and second wafers. Further, the dislocation may also be suppressed.

In example embodiments, the wafer bonding apparatus may further include a camera, a moving stage, and a controller. The camera may detect an alignment of the wafer chucked by the second chuck. The moving stage may move the second chuck. The controller may control movements of the moving stage based on the alignment of the wafer detected by the camera to align the first chuck with the second chuck.

According to example embodiments, the dislocation caused by the distortion of the wafer may be suppressed to accurately bond the wafers to each other without the void.

In example embodiments, the moving stage may include an XY stage moved in an X-direction and a Y-direction. The XY stage may align the wafer based on an alignment mark of the second wafer.

According to example embodiments, the wafer may be aligned in horizontal position corresponding to the X-direction and the Y-direction.

In example embodiments, the moving stage may further include a Z stage moved in a Z-direction. The camera may photograph the alignment mark of the second wafer on the Z-stage. The XY stage may align the wafer in the X-Y directions based on position changes of the alignment mark before and after the Z-stage is moved in the Z-direction.

According to example embodiments, the wafer may be accurately aligned by correcting a reproducibility error of a Z-driving shaft.

In example embodiments, the wafer bonding apparatus may further include a wide vision camera. The wide vision camera may photograph a spreading state of bonded surfaces between the first and second wafers after pressurizing the first wafer to the second wafer. The pressure device may selectively pressurize the wafers in variable wafer pressure times.

According to example embodiments, the spreading state of the bonding surfaces between the wafers may be monitored and the wafer pressure times may be changed in accordance with the spreading state of the bonding surfaces between the wafers to increase the productivity. Further, when a contamination such as a particle exists in the pressure device, a spreading speed of the wafer bonding may be abnormally delayed. Thus, the bonding error may be previously detected by managing the spreading time.

According to example embodiments, the wafer bonding apparatus may accurately control the warpage and the parallelism of the wafers, suppress the dislocation of the wafers, accurately bond the wafers to each other without a void, and improve the productivity by monitoring the bonding process of the wafers.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating a wafer bonding apparatus in accordance with example embodiments;

FIG. 2 is a perspective view illustrating the wafer bonding apparatus in FIG. 1;

FIG. 3 is a perspective view illustrating the wafer bonding apparatus in FIG. 1;

FIG. 4 is a cross-sectional view illustrating operations of the wafer bonding apparatus in

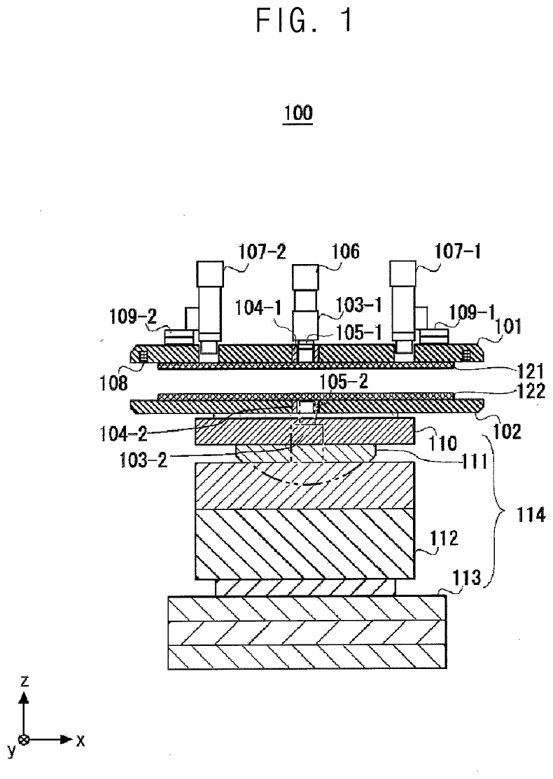

FIG. 1;

FIG. 5 is a cross-sectional view illustrating operations of the wafer bonding apparatus in FIG. 1;

FIG. 6 is a perspective view illustrating a tilt stage of the wafer bonding apparatus in FIG. 1;

FIG. 7 is a cross-sectional view illustrating an alignment operation of the wafer bonding apparatus in FIG. 1;

FIG. 8 is a flow chart illustrating operations of the wafer bonding apparatus in FIG. 1; and

FIG. 9 is a flow chart showing a method of manufacturing a semiconductor device using a wafer bonding apparatus.

### DETAILED DESCRIPTION OF THE EMBODIMENTS

Hereinafter, example embodiments will be explained in detail with reference to the accompanying drawings.

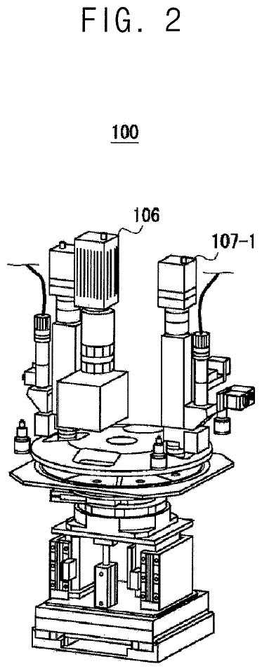

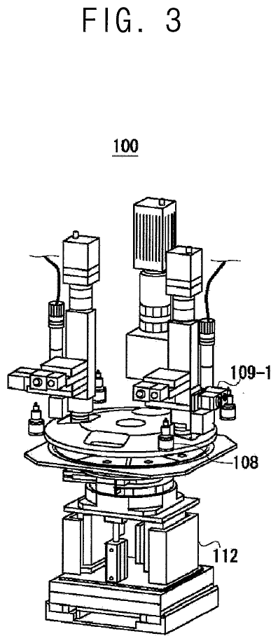

FIG. 1 is a cross-sectional view illustrating a wafer bonding apparatus in accordance with example embodiments, FIG. 2 is a perspective view illustrating the wafer bonding apparatus in FIG. 1, and FIG. 3 is a perspective view illustrating the wafer bonding apparatus in FIG. 1.

Referring to FIG. 1, a wafer bonding apparatus 100 may include a first chuck 101, a second chuck 102, pushers 103-1 and 103-2, air bearings 104-1 and 104-2, load cells 105-1 and 105-2, a first camera 106, second cameras 107-1 and 107-2, a sensor 108, XYZ stages 109-1 and 109-2, a theta stage 110, a tilt stage 111, a Z stage 112 and an XY stage 113. A wafer stage 114 may include the theta stage 110, the tilt stage 111, the Z stage 112 and the XY stage 113.

The first chuck 101 may include a hole formed through a central portion of the first chuck 101. In FIG. 1, the first chuck 101 may be positioned over the second chuck 102. The first chuck 101 may be configured to chuck (e.g., hold, adhere, or adsorb) a first wafer 121.

The second chuck 102 may include a hole formed through a central portion of the second chuck 102. In FIG. 1, the second chuck 102 may be positioned under the first chuck 101. The second chuck 102 may be configured to chuck (e.g., hold, adhere, or adsorb) a second wafer 122.

The pusher 103-1 may pressurize (e.g., exert pressure on) the first wafer 121 toward the second chuck 102 through the hole of the first chuck 101. The pusher 103-1 may be, for example, a rod with a flat end that pushes against the wafer 121. The pusher 103-2 may pressurize (e.g., exert pressure on) the second wafer 122 toward the first chuck 101 through the hole of the second chuck 102. The pusher 103-2 may be, for example, a rod with a flat end that pushes against the wafer 121. The pushers 103-1 and 103-2 may function as a pressure device. For example, pushers 103-1 and 103-2 may form or function as a clamp or vise having two separate fixed pieces, each connected to a mechanical or electro-mechanical actuator for moving the flat ends of the pushers toward each other in order to put pressure on the two wafers.

The air bearing 104-1 is arranged between the pusher 103-1 and the first chuck 101 in the hole of the first chuck 101. The air bearing 104-1 may be configured to suppress a position dislocation of the pusher 103-1 on a chucking surface, i.e., a lower surface of the first chuck 101 on which the first wafer 121 may be chucked. The air bearing 104-2 may be arranged between the pusher 103-2 and the second chuck 102 in the hole of the second chuck 102. The air bearing 104-2 may be configured to suppress a position dislocation of the pusher 103-2 on a chucking surface, i.e., an upper surface of the second chuck 102 on which the second wafer 122 may be chucked.

The load cell 105-1 may correspond to a force sensor configured to measure a load applied to the first wafer 121 by the pusher 103-1. The load cell 105-1 may be attached to a lower end of the pusher 103-1. The load cell 105-2 may correspond to a force sensor configured to measure a load applied to the second wafer 122 by the pusher 103-2. The load cell 105-2 may be attached to an upper end of the pusher 103-2.

The first camera 106 is arranged to monitor bonding states between the first and second wafers 121 and 122. For example, the first camera 106 may include an InGaAs image sensor. The first camera 106 will be illustrated later in detail.

The second cameras 107-1 and 107-2 are arranged to monitor an alignment between the first and second wafers 121 and 122. For example, the second cameras 107-1 and 107-2 may each include an InGaAs image sensor. The second cameras 107-1 and 107-2 will be illustrated later in detail.

The sensor 108 is configured to detect a tilt between the first wafer 121 and the second wafer 122, i.e., an inclined angle between the first wafer 121 and the second wafer 122.

The XYZ stage 109-1 is configured to move the second camera 107-1 in XYZ directions. The XYZ stage 109-2 is configured to move the second camera 107-2 in the XYZ directions.

The theta stage 110 is configured to rotate the second chuck 102 on an XY plane with respect to a Z-axis.

The tilt stage 111 is configured to change a tilt angle of the second chuck 102 with respect to the Z-axis.

The Z stage 112 is configured to move the second chuck 102 along the Z-axis.

The XY stage 113 is configured to move the second chuck 102 on the XY plane.

In one embodiment, the above-mentioned elements are controlled by a controller. The controller will be illustrated later in detail.

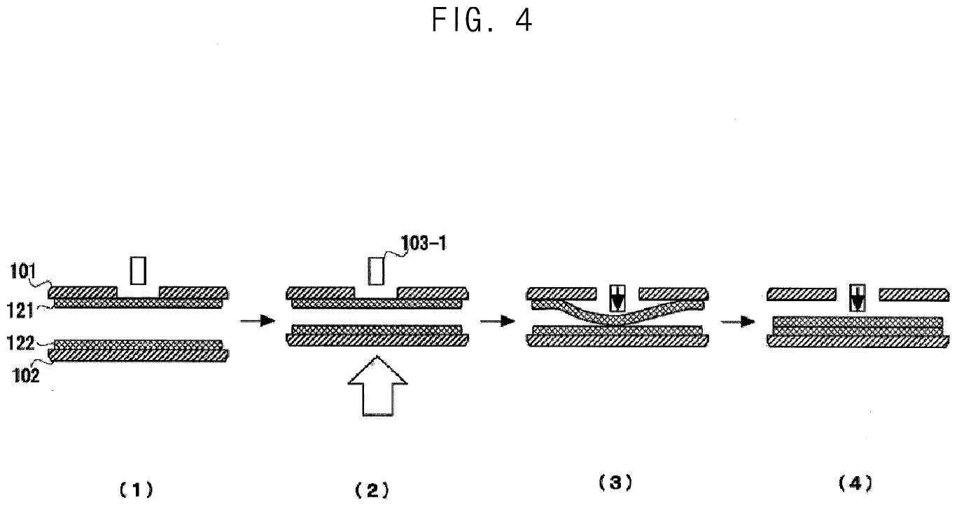

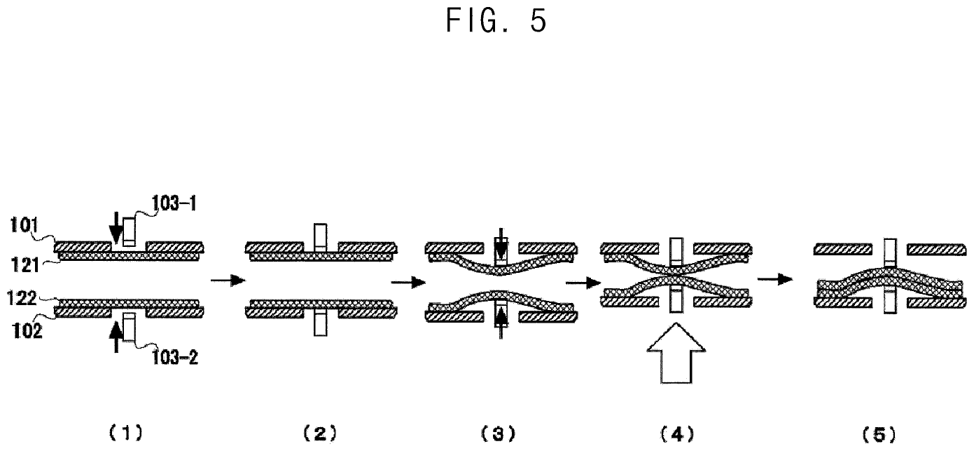

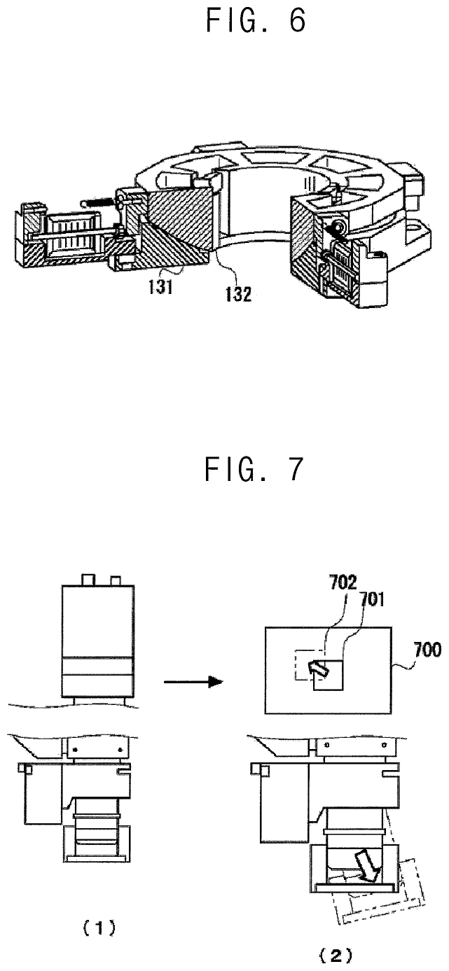

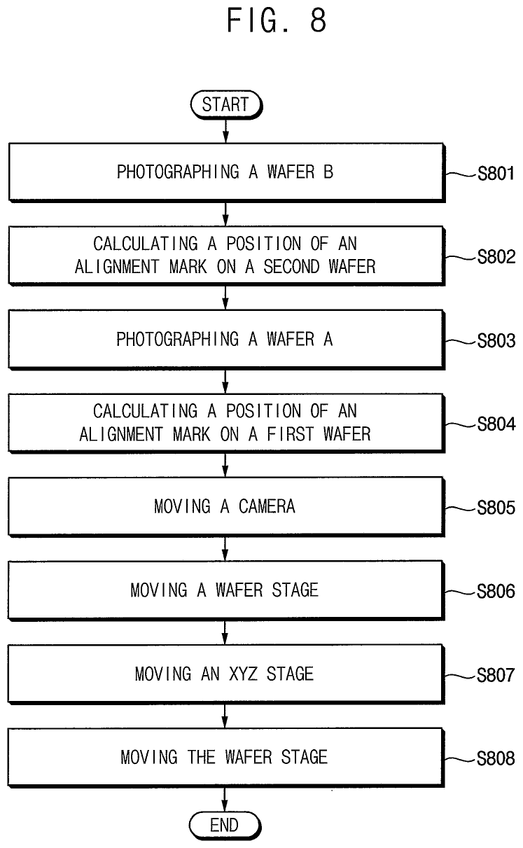

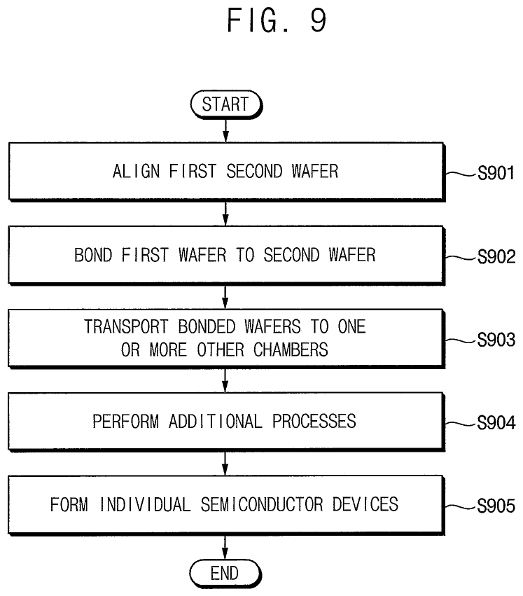

FIG. 4 is a cross-sectional view illustrating operations of the wafer bonding apparatus in FIG. 1, according to some embodiments. FIG. 4 shows the first wafer 121 pressurized by the pusher 103-1 from the first chuck 101.

Referring to FIG. 4 (1), bonding surfaces of the first and second wafers 121 and 122 transferred by a transfer device face each other. The first chuck 101 chucks the first wafer 121. The second chuck 102 chucks the second wafer 122.

Referring to FIG. 4 (2), the first wafer 121 and the second wafer 122 are aligned with each other (e.g., in an XY direction) by the first chuck 101 and the second chuck 102.

Referring to FIG. 4 (3), the pusher 103-1 pressurizes a central portion of the first wafer 121. Thus, the central portion of the first wafer 121 makes contact with the second wafer 122. The term “contact” or “contacting” as used herein refers to a direct connection, e.g., touching.

Referring to FIG. 4 (4), the whole surface of the first wafer 121 may contact the second wafer 122.

Alternatively, referring to FIG. 5, the pushers 103-1 and 103-2 may simultaneously pressurize the first wafer 121 and the second wafer 122, respectively.

Referring to FIG. 5 (1), the bonding surfaces of the first and second wafers 121 and 122 transferred by the transfer device face each other. The first chuck 101 chucks the first wafer 121. The second chuck 102 chucks the second wafer 122.

Referring to FIG. 5 (2), the first wafer 121 and the second wafer 122 are aligned with each other (e.g., in an XY direction) by the first chuck 101 and the second chuck 102.

Referring to FIG. 5 (3), the pusher 103-1 pressurizes the central portion of the first wafer 121. Simultaneously, the pusher 103-2 pressurizes a central portion of the second wafer 122.

Thus, as shown in FIG. 5 (4), the central portion of the first wafer 121 makes contact with the second wafer 122.

Referring to FIG. 5 (5), the whole surface of the first wafer 121 may contact the second wafer 122.

Therefore, the central portions of the wafers may make contact with each other by pressurizing the central portions of the wafers. The wafers may then be bonded to each other.

Hereinafter, a tilt correction of the wafers is illustrated in detail.

The bonding surfaces of the first and second wafers 121 and 122 transferred by the transfer device face each other. The first chuck 101 chucks the first wafer 121. The second chuck 102 chucks the second wafer 122. When the first wafer 121 and/or the second wafer 122 are tilted with respect to a horizontal direction, although a narrow gap may be formed between the first wafer 121 and the second wafer 122, edge portions of the first and second wafers 121 and 122 may make contact with each other, for example, before other portions. Thus, the parallelism of the wafers 121 and 122 may be corrected using the tilt stage 111.

In one embodiment, in order to perform the parallelism correction, the sensor 108 adjacent to the first chuck 101 measures a distance between the first chuck 101 and the second chuck 102 to correct the parallelism of the first and second wafers 121 and 122. In order to prevent a contact between the sensor 108 and the wafer, the sensor 108 may be placed in a groove at the chucking surface of the first chuck 101. Previous to performing sensing, an offset between the chucking surface of the first chuck 101 and the sensor 108 may be calibrated using a jig such as a flat plate.

The sensor 108 may be fixed to the first chuck 101. The sensor 108 may be one of a plurality of such sensors 108 (e.g., three or four) for sensing tilt. In one embodiment, because the wafer has a circular shape, four sensors 108 or the three sensors 108 may be positioned at corners of the rectangular first chuck 101 to reduce an area of the first chuck 101. The chucks 101 and 102 may include a material such as a ceramic that is not influenced much by expansion and contraction caused by a heat. In some embodiments, when the chucks 101 and 102 chuck the wafer in horizontality to have a tilt-caused gap of no more than about 2 μm, the chucks 101 and 102 may not bring about a warpage of the wafer. Thus, in one embodiment, when all of the tilt sensors used (e.g., 3 or 4) register a gap of no more than about 2 μm, the tilt is determined to be within an acceptable range.

FIG. 6 is a perspective view illustrating a tilt stage of the wafer bonding apparatus in FIG. 1.

Referring to FIG. 6, the tilt stage 111 may correct the tilt of the wafer in accordance with a value measured by the sensor. The tilt stage 111 may include a fixed block 131 and a correcting block 132 movable on the fixed block 131. The fixed block 131 may include an upper surface having a semi-spherical shape. The correcting block 111 may have a lower surface having a semi-spherical shape. The semi-spherical shaped upper surface of the fixed block 131 may be configured to movably support the semi-spherical shaped lower surface of the correcting block 132. The fixed block and correcting block may form a ball and socket joint, or a portion of a ball and socket joint. The tilt correction may include moving the correcting block 111 until the tilt sensors register an acceptable range for a tilt-caused gap.

The semi-spherical shaped upper surface of the fixed block 131 may include a porous shape. When air is supplied to the correcting block 132 through the porous fixed block 131, the correcting block 132 may be floated from the fixed block 131. “Air” as described herein can refer to atmospheric air, or to other gasses selectively supplied to the system. A device configured to press the floated correcting block 132 in two lateral directions may correct the tilt of the wafer. A floated height of the correcting block 132 may be controlled by a pressure and a flux of the air. For example, the floated height of the correcting block 132 may be about 5 μm to about 10 μm. After correcting the tilt, the supplying of the air may be stopped. Simultaneously, the semi-spherical surfaces of the fixed block 132 and the correcting block 132 may closely make contact with each other using, for example, a magnet to fix an angle of the tilt stage 111. When the angle of the tilt stage 111 is fixed after being in floating the correction block 132, the angle of the tilt stage 111 may be slightly changed, based on the change from being floating to being fixed. Thus, the wafer bonding apparatus 100 may store pre-determined tilt changes based on different values of angles and heights. Before fixing the tilt stage 111 from the floating state, the tilt stage 111 may be corrected, using the pre-determined stored tilt changes, to compensate for the slight change due to the transition from floating to fixed states. Thus, the tilt stage 111 can be fixed to a predicted position based on the stored tilt changes. As a result, the tilt stage 111 may be fixed to provide the chucks with the parallelism.

Conventionally, the parallelism of the chucks may be obtained by contacting the chucks with each other at a height different from an actual bonding height. However, when the chuck is not at that different height during actual bonding, the parallelism of the chuck may not be secured at the actual bonding height. In contrast, according to example embodiments, the tilt stage 111 may be movable in the vertical direction to adjust the parallelism of the chuck at the actual bonding height.

Hereinafter, operations of the wafer bonding apparatus are illustrated in detail.

The bonding surfaces of the first and second wafers 121 and 122 transferred by the transfer device face each other. The first chuck 101 is configured to chuck (e.g., hold) the first wafer 121. The second chuck 102 is configured to chuck (e.g., hold) the second wafer 122. The second cameras 107-1 and 107-2 are configured to recognize positions of the first and second wafers 121 and 122, for example, by photographing alignment marks on the first and second wafers 121 and 122.

The second wafer 122 may be moved by the XY stage 113 attached to the second chuck 102. The XY stage 113 is configured to be moved in accordance with a position of the alignment mark on the first wafer 121 to align the first wafer 121 chucked by the first chuck 101 with the second wafer 122 chucked by the second chuck 102. A rotation angle of the first wafer 121 may be measured from positions of the second cameras 107-1 and 107-2. The theta stage 110 is configured to adjust a rotation angle of the second wafer 122 in accordance with the rotation angle of the first wafer 121. The various detections, alignments, and movements described herein may be controlled by a controller system, for example, including a computer having hardware and software configured to perform detection and alignment, to calculate adjustment amounts, and to control one or more motors or actuators to control movement and other functions described herein.

The pressure device is configured to pressurize the central portions of the first wafer 121 and the second wafer 122. In one embodiment, in order to control pressures applied to the first and second wafers 121 and 122, the sensor, i.e., the load cells 105-1 and 105-2 detects forces applied to the first and second wafers 121 and 122. The load cells 105-1 and 105-2 may detect the forces of about 0.1N applied to the first and second wafers 121 and 122 from the pusher 103 to control the pressure.

A sensor such as a position sensor (e.g., an encoder) may be attached to the pressure device. The sensor is configured to calculate the pressure from a position of the chucking surface based on a thickness of the wafer. The pushers 103-1 and 103-2 are configured to pressurize the first and second wafers 121 and 122 by the calculated pressure to bend the first and second wafers 121 and 122 with respect to the chucking surfaces.

Each of the first and second chucks 101 and 102 may have a central chucking function and an edge chucking function separated from the central chucking function. When the central portion of the wafer is pressurized, the edge chucking function of each of the first and second chuck 101 and 102 is configured to operate so that it chucks only the edge portion of each of the first and second wafers 121 and 122. For example, a control program may control a suction used for adsorption to only be applied at the edge portions depending on the amount of pressure being exerted by the pushers 103-1 and 103-2.

The first and second wafers 121 and 122 may be bent to control shapes of the first and second wafers 121 and 122, thereby reducing influences of the expansion and contraction when the first and second wafers 121 and 122 are bonded to each other. However, when the position location of the pusher is generated in pressurizing the wafer, a dislocation of a pressured portion on the wafer may also be generated. The dislocation of the pressured portion on the wafer may cause an undesired deformation of the wafer to generate a misalignment between the bonded wafers.

According to example embodiments, a guide is arranged in the holes of the first and second chucks 101 and 102. The guide may include the air bearings 104-1 and 104-2. The air bearings 104-1 and 104-2 may guide the pusher to suppress the dislocation of the pusher. Alternatively, the guide may include a spline configured to suppress the dislocation of the pusher. However, the load cell configured to accurately detect the position of the wafer may be attached to the pusher. When a sliding resistance is generated from the spline, the load cell may not accurately detect the load. Thus, the air bearing without the sliding resistance may be preferably used for the guide.

In some embodiments, during the first and second wafers 121 and 122 being pressurized, the second chuck 102 is upwardly moved by a lifter to place the bent apexes (e.g., bent edges) of the first and second wafers 121 and 122 in close proximity. The load cell attached to the pressure device detects the load as the bent apexes of the first and second wafers 121 and 122 contacts each other and are pressured toward each other. In one embodiment, when the load reaches a preset value, such as about 10N to about 20N, the lifter is stopped. The bent apexes of the first and second wafers 121 and 122 are then attached to each other.

Before the load reaches the preset value (e.g., about 10N), the close location of the bent apexes may be stopped at a height at which a contact between the first and second wafers 121 and 122 is generated. After this occurs, the first and second wafers 121 and 122 may then be pressurized to a set load, such as the 10N.

After fully attaching the first and second wafers 121 and 122 to each other, the first and second wafers 121 and 122 are released from the first and second chucks 101 and 102, respectively, thereby bonding the first and second wafers 121 and 122 to each other.

According to example embodiments, the wide vision camera as well as the camera configured to align the wafers with each other may monitor the spreading state of the bonding surfaces between the wafers, and the wafer pressure times may be changed in accordance with the spreading state of the bonding surfaces between the wafers to increase the productivity. Further, when a contamination such as a particle exists in the pressure device, a spreading speed of the wafer bonding may be abnormally delayed. Thus, the bonding error may be determined based on a previously stored set of spreading times (e.g., based on testing), so that for a given pressure, wafer size, wafer type, etc., if the spreading time is not within a particular range, a bonding error can be noted.

By operating as discussed above, the wafer bonding apparatus may accurately control the warpage and the parallelism of the wafers, suppress the dislocation of the wafers, accurately bond the wafers to each other without a void, and improve the productivity by monitoring the bonding process of the wafers.

FIG. 7 is a cross-sectional view illustrating an alignment operation of the wafer bonding apparatus in FIG. 1.

Referring to FIG. 7 (1), the pusher 103-1 may be driven along the Z-direction. As shown in FIG. 7 (2), a horizontal dislocation of the pusher 103-1 along the XY-directions may be generated. The dislocation of the pusher 103-1 may be corrected using offsets generated in a sensor by a Z-axis runout, a crosstalk, etc., as parameters. Particularly, in an image generated by the first camera 106 as shown in FIG. 7, the dislocation of the pusher 103-1 may be corrected based on a position difference between an alignment mark 701 before driving the pusher 103-1 and an alignment mark 702 after driving the pusher 103-1. For example, due to driving of the pusher, the alignment mark 702 may be dislocated from the alignment mark 701. Therefore, to account for this dislocation, an offset may be set prior to the pushing function.

According to example embodiments, when the bonding position is aligned with the position of the second chuck, the Z-driver such as a piezo stage may focus on the alignment mark. The reproducibility error of the horizontal position of the Z-driving shaft may be corrected to perform the accurate alignment.

Position alignments by the first camera 106 and the second cameras 107-1 and 107-2 are now discussed in detail.

The first camera 106 may include imaging elements such as imaging devices, a lens, an illumination, etc. The imaging element of the first camera 106 may include an imaging element including an InGaAs sensor that has a sensitivity of a short infrared wavelength band. Alternatively, the first camera 106 may include an imaging element having the sensitivity of the short infrared wavelength band without the InGaAs sensor. In one embodiment, the lens of the first camera 106 allows a light having the short infrared wavelength band to pass therethrough. The illumination by the first camera 106 may emit the light having the short infrared wavelength band.

The first camera 106 may be arranged at the edge portion of the wafer. For example, the position of the first camera 106 may be located within a region between a circle formed half-way along the radius of the wafer up to a circumference of the wafer. The first camera 106 may function as to measure dislocations of the wafer with respect to the X-direction, the Y-direction and the θ-direction.

The first camera 106 may be arranged at a region where the θ dislocation may be greatly shown to recognize the minute θ dislocation. Further, in order to rapidly set the position of the first camera 106, the first camera 106 may photograph without any movement. Because the first camera 106 may obtain the dislocation from the photographed image, the first camera 106 may include a wide vision camera capable of photographing under a condition that allows uniform standard to be set in a photography region regardless of the dislocation. Thus, the image sensor of the first camera 106 may have a size substantially equal to or no less than a size of the image sensor of the second cameras 107-1 and 107-2, which allow for high resolution. Further, a magnification of the lens of the first camera 106 may be lower than a magnification of the lens of the second cameras 107-1 and 107-2.

A photograph region of the first camera 106 may have a magnification that covers a certain field of view so that the region of interest within the frame is large enough to remain in the frame even though a transfer position of the wafer may not be uniform. This adds flexibility to allow for a greater deviation of transfer accuracy. For example, a magnification can be used so that an exposing size of about 33 mm to about 26 mm of one shot, or a size of one chip, remains in the frame even if a transfer position of the wafer is not uniform. A pixel size in the image of the first camera 106 may have a magnification in which a pixel size is no smaller than a width of a scribe lane so as to photograph information for checking a transfer dislocation of the wafer, for example, when the transfer dislocation is checked using the scribe lane or an intersected point between the scribe lanes.

The second cameras 107-1 and 107-2 may include elements such as an imaging device, a lens, an illumination, etc. The second cameras 107-1 and 107-2 may include a Z-axis stage configured to lift the second cameras to adjust a focus.

The imaging element of the second cameras 107-1 and 107-2 may include an imaging element including an InGaAs sensor having a sensitivity of a short infrared wavelength band. Because it may be required to accurately detect the alignment mark, in one embodiment, a pixel size of the imaging element in the second cameras 107-1 and 107-2 is no larger than the pixel size of the first camera 106. The lens of the second cameras 107-1 and 107-2 may allow a light having the short infrared wavelength band to pass therethrough.

Because the alignment mark should be accurately detected, the lens of the second cameras 107-1 and 107-2 may have a magnification substantially equal to or greater than the magnification of the first camera 106. Because the second cameras 107-1 and 107-2 may have the high magnification and a depth of a field in the second cameras 107-1 and 107-2 may be shallow, the second cameras 107-1 and 107-2 differently from the first camera 106 may include the Z-axis stage for adjusting the focus. The illumination of the second cameras 107-1 and 107-2 may emit the light having the short infrared wavelength band.

When the wavelength of the second cameras 107-1 and 107-2 is different from the wavelength of the first camera 106, the wavelength of the first camera 106 may be about 1,450 nm and the second cameras 107-1 and 107-2 may be about 1,300 nm. The first camera 106 may observe the scribe lane as well as the alignment mark. The alignment mark may be recognized by the spaced two cameras to accurately obtain the dislocation with respect to the rotation direction. The second cameras 107-1 and 107-2 may have substantially the same configuration.

The XYZ stage 109 may move the second cameras 107-1 and 107-2 to a position at which the second cameras 107-1 and 107-2 are capable of photographing the whole alignment mark.

The first wafer 121 and the second wafer 122 may include the scribe lane, the alignment mark on a metal layer, a wiring pattern, etc.

The first chuck 101 and the second chuck 102 may be configured to chuck the respective wafers. The first chuck 101 and the second chuck 102 may include a vacuum device configured to adsorb the wafer using vacuum.

The wafer stage 114 may be configured to hold the second chuck 102. The wafer stage 114 may have the X-axis, the Y-axis, the θ-axis and the Z-axis to eliminate the dislocation of the first wafer 121 and the second wafer 122.

A controller for the above components may include a central processing unit (CPU). The controller may communicate with the cameras via a gigabit Ethernet (GigE), a camera link, etc. The images photographed by the cameras may be transmitted to the controller. The controller may communicate with the stages via an Ethernet for control automation technology (Ethercat), a universal serial bus (USB), etc. The controller may be configured to control the movements of the stages.

The positions of the wafers may be aligned with each other using the above-mentioned configuration. Hereinafter, operations of the wafer bonding apparatus are illustrated in detail. FIG. 8 is a flow chart illustrating operations of the wafer bonding apparatus in FIG. 1.

In step S801, the first camera 106 photographs the second wafer 122 to obtain an image B. In some embodiments, because the first camera 106 does not observe a patterned surface of the metal layer, the first camera 106 does not photograph the whole surface of the second wafer 122 during the second chuck 102 holding the second wafer 122. The first camera 106 may photograph the second wafer 122 under a condition where the first chuck 101 is not holding the first wafer 121. To perform the photographing of the second wafer 122, the second wafer 122 may be transferred to the second chuck 102 by a transfer robot. The second chuck 102 may chuck the second wafer 122 using a vacuum. The Z-axis of the wafer stage 114 may be moved to locate the first camera 106 at a focusing position with respect to the second wafer 122. The first camera 106 may then photograph the second wafer 122.

The intended transferred position of the wafer by the transfer robot may be previously set. However, when repetition accuracy of the transferred position is inconsistent or varies, such that a field of view of the second cameras 107-1 and 107-2 does not include certain parts of the wafer 122, the second cameras 107-1 and 107-2 may not be able to photograph the alignment mark at the transferred position. Thus, the second cameras 107-1 and 107-2 or the wafer may be moved to check an exposed position of the alignment mark.

In step S802, a mark photograph position B of the second wafer 122 is calculated from the image B. The mark photograph position B may be calculated using a coordinate of the alignment mark on the XYZ stage 109 as a reference coordinate, and a reference image photographed by the first camera 106.

The reference coordinate and the reference image may be determined by raising the wafer stage 114 to the focus position of the first camera 106 with a wafer mounted thereon, which wafer may have a pattern substantially the same as that of the second wafer 122. The first camera 106 may photograph the wafer at the focus position to determine a photographed image as the reference image. The XYZ stage 109 may be moved to determine the coordinate of the XYZ stage 109 at the mark photograph position as the reference coordinate.

A mark photograph initial coordinate as a coordinate of the XYZ stage 109 configured to expose the alignment mark may be obtained using the second cameras 107-1 and 107-2. Thus, because a range for searching the reference coordinate by moving the XYZ stage 109 may be restricted within a deviation range of the deviation of the wafer transfer accuracy, in some embodiments, it is not required to wholly search the wafer so that the process may be simplified.

In one embodiment, the dislocation, or difference in location, between the reference image and the wafer image B is obtained. The reference coordinate is then adjusted to a position offset by the obtained dislocation. The adjusted position may then be used as the mark photograph position.

The dislocation between the reference image and the wafer image may be obtained using a template matching. For example, a template including a partial cut or section of the reference image may be matched with the wafer image with the parameters such as X, Y and θ being changed. For example, the template may not initially match the reference image because of misalignment. Therefore, the X, Y and θ values may be adjusted to result in closer alignment of the reference image with the wafer image. When an alignment is achieved such that the reference image is maximumly matched with the wafer image, the X, Y and θ values at that position may be determined as the dislocation. Change widths of the parameters may be an accuracy of the dislocation. Alternatively, an interpolation may be performed using the maximum parameters and peripheral parameters from a three-dimensional match map of the X, Y and θ to obtain the dislocation having accuracy higher than the change widths.

Values for the above-described parameters may be rapidly obtained by determining local regions, which may include a specific pattern such as the scribe lane, from the reference image, performing the template matching to obtain the X and Y with respect to each of the local regions, and determining optimal X, Y and θ where a distance between corresponding points (e.g., between the reference image and wafer image) in each of the local regions may be minimum in the total local regions.

In some embodiments, the patterns of the X and Y may be more easily matched with each other because the rotation θ may be slight and a change of the image caused by the rotation may also be small. Thus, searched numbers of the parameters using the template matching may be less than searching the total X, Y and θ. Further, the number of pixels being accessed may be reduced due to the local region of the template matching. As a result, a process time may be curtailed. The optimal X, Y and θ may be obtained using a downhill simplex manner not requiring a differential of a Cost Function with respect to a plurality of variables. The Cost Function may be set as an average value of distances between the corresponding points on the reference image obtained from the XY template matching and the wafer image in the total local regions. Alternatively, when a result of the template matching includes a dislocation value, the Cost Function may be set to a central value, not the average value in the total local regions, to eliminate the influence of the dislocation value.

After obtaining the dislocation value, a coordinate of the XYZ stage 109 exposed to the second cameras 107-1 and 107-2 may be calculated. A conversion equation of the coordinate of the wafer stage 114 and the coordinate of the XYZ stage 109 may be previously set. The reference coordinate may be converted into the coordinate of the wafer stage 114. The reference coordinate on the wafer stage 114 may be moved using the dislocation of the X, Y and θ. The reference coordinate may then be converted into the coordinate of the XYZ stage 109.

The conversion equation may be obtained by holding a calibration pattern wafer at the wafer stage 111, by photographing movements of the patterns in accordance with the movements of the wafer stage 114 in the X-axis, the Y-axis and the θ-axis by the first camera 106 and the second cameras 107-1 and 107-2, and by measuring the movements of the patterns.

For example, the wafer stage 114 may hold the calibration pattern wafer. The first camera 106 and the second cameras 107-1 and 107-2 at a starting point of the XYZ stage 109 may photograph the patterns of the calibration pattern wafer to obtain center positions of the first camera 106 and the second cameras 107-1 and 107-2 because the position relationship between the patterns is known.

The first camera 106 may photograph the wafer stage 114 before and after rotating the wafer stage 114 with respect to the θ-axis. A rotation center of the wafer stage 114 may be calculated based on the movements of the patterns and the rotation angles of the two images before and after rotating the wafer stage 114.

The first camera 106 or the second cameras 107-1 and 107-2 may photograph the pattern with the wafer stage 114 being moved in the XY directions. The movement of the pattern caused by the movement of the wafer stage 114 may be obtained to calculate the relative relation between the cameras and the X-axis and the Y-axis of the wafer stage 114.

The XYZ stage 109 may move the pattern with the second cameras 107-1 and 107-2 being moved to calculate the relative relation between the XYZ stage 109 and the second cameras 107-1 and 107-2.

In step S803, the first wafer 121 may then be transferred. The first camera 106 may photograph the first wafer 121 to obtain a wafer image A.

In step S804, a mark photograph position A at which the alignment mark of the first wafer 121 is exposed to the second cameras 107-1 and 107-2 is obtained. The reference coordinate and the reference image obtained using a wafer having a pattern substantially the same as that of the first wafer 121 may be used.

In step S805, the first camera 106 is moved to the mark photograph position A.

In step S806, the wafer stage 114 is moved to decrease a distance between the mark photograph positions A and B. Thus, the second cameras 107-1 and 107-2 at the mark photograph position A may photograph a region through which a light having the short infrared wavelength band passes, for example, the alignment mark of the second wafer 122 over the scribe lane.

In step S807, the alignment mark of the first wafer 121 may be located within the vision of the second cameras 107-1 and 107-2. However, the alignment mark of the first wafer 121 may not be located at a center of a vision in the mark photograph position obtained using the first camera 106 having the low magnification. Because a central portion of a lens may have the highest performance, the stage may be moved to locate the alignment mark at the center of the vision, thereby accurately locating the positions.

The second cameras 107-1 and 107-2 may be moved to a position focused on the alignment mark of the first wafer 121 to recognize the position of the alignment mark on the first wafer 121. A relative distance between the center point of the alignment mark and the center point of the image obtained from the second cameras 107-1 and 107-2 may be obtained. The XYZ stage 109 may be moved to decrease the relative distance, thereby positioning the alignment mark of the first wafer 121 at the center of the photographing range of the second cameras 107-1 and 107-2.

The second cameras 107-1 and 107-2 may then be moved to a position focused on the alignment mark of a wafer B to recognize the position of the alignment mark on the wafer B. A relative distance between the center point of the alignment mark and the center point of the image obtained from the second cameras 107-1 and 107-2 may be obtained. The XYZ stage 109 may be moved to decrease the relative distance, thereby positioning the alignment mark of the wafer B at the center of the photographing range of the second cameras 107-1 and 107-2.

In step S808, the alignment marks of the first wafer 121 and the second wafer 122 may again be identified. The wafer stage 114 may be moved to reduce the position dislocation between the alignment marks, thereby performing the position location.

According to example embodiments, the movement of the stage for obtaining the mark photograph position may not be required. In contrast, the first camera 106 may once photograph to obtain the mark photograph position, thereby reducing the alignment time.

Further, the wafer bonding apparatus may include any one of the pushers 103-1 and 103-2.

FIG. 9 shows a method of manufacturing a semiconductor device, according to example embodiments.

In step S901, a first wafer and second wafer are aligned on a first and second chuck. For example, the alignment may be performed based on the various methods and using the apparatus such as described in connection with FIGS. 1-3 and 6-8.

In step S902, the first wafer and second wafer are bonded together. For example they may be bonded together using the method and equipment described in connection with FIGS. 1-5. In addition, the bonding may include a heating process. For example, in some embodiments, two wafers are bonded together at their surfaces, and certain metal portions from each wafer are bonded to each other, while certain insulation material portions of each wafer are bonded to each other.

In step S903, the bonded wafers are transported to one or more other chambers for further processing. For example, the bonded wafers may be transported to a chamber used for adding further layers or components on the wafers.

In step S904, in these other chambers, additional processes, such as etching, adding additional layers, forming through vias, and other processes for forming the semiconductor device may be carried out. The semiconductor device may be, for example, a semiconductor memory chip, or semiconductor logic chip including integrated circuits formed thereon. Step S904 may further include mounting the bonded and processed wafer (e.g., a wafer of semiconductor chips) onto a substrate such as a package substrate, connecting the processed wafer to the substrate, and optionally forming a mold layer to cover the package substrate and bonded wafers.

In step S905, individual semiconductor devices, such as semiconductor chips or semiconductor packages are formed. For example, cutting may be performed, using a laser or other cutting device, to form individual semiconductor chips or packages. A different chamber may be used for this step as well.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A wafer bonding apparatus comprising:
a first chuck having a hole formed through the first chuck on a chucking surface of the first chuck;
a second chuck;
a pressure device configured to pressurize a wafer toward the second chuck through the hole; and
an air bearing arranged between the pressure device and the first chuck to suppress a position dislocation of the pressure device along the chucking surface.

2. The wafer bonding apparatus of claim 1, wherein the pressure device comprises a force sensor configured to detect a contact between the pressure device and the wafer.

3. The wafer bonding apparatus of claim 1, further comprising:
a sensor configured to detect a tilt between a first wafer chucked by the first chuck and a second wafer chucked by the second chuck; and
a tilt stage configured to control a tilt of the second chuck based on the tilt between the first and second wafers to provide the first and second wafers with a parallelism.

4. The wafer bonding apparatus of claim 3, further comprising:
a camera configured to detect an alignment of the second wafer on the second chuck;
a moving stage configured to move the second chuck; and
a controller configured to move the moving stage based on detection results of the camera to align a position of the second chuck with the first chuck.

5. The wafer bonding apparatus of claim 4, wherein the moving stage comprises an XY stage moved in XY directions, and the XY stage is configured to align the wafer based on a position of an alignment mark on the second wafer.

6. The wafer bonding apparatus of claim 5, wherein the moving stage further comprises a Z-stage moved in a Z direction, the camera is configured to photograph the alignment mark of the second wafer moved in the Z direction, and the XY stage is configured to align a position of the second wafer in the XY directions based on position changes of the alignment mark before and after the alignment mark is moved.

7. The wafer bonding apparatus of claim 6, further comprising a wide vision camera configured to photograph a spreading state of bonded surfaces between the first and second wafers after pressurizing the first wafer to the second wafer,
wherein the pressure device is configured to selectively pressurize the first and second wafers in variable wafer pressure times.
